(19) United States
(12) Patent Application Publication
(10) Pub. No.: US 2018/0145283 A1
(43) Pub. Date: May 24, 2018

(54) OLED DISPLAY MODULE

(71) Applicant: UNIVERSAL DISPLAY CORPORATION, Ewing, NJ (US)

(72) Inventor: MIchael Hack, Carmel, CA (US)

(21) Appl. No.: 15/727,527

(22) Filed: Oct. 6, 2017

Related U.S. Application Data
(60) Provisional application No. 62/425,961, filed on Nov. 23, 2016.

(51) Int. Cl. H01L 51/52; H01L 27/32; H05B 33/08; H05B 37/02; G02F 1/01

(52) U.S. Cl. CPC H01L 51/5293; H01L 27/3227; H05B 37/0227; H05B 37/0218; G02F 1/0126; H05B 33/0896

(57) ABSTRACT

Some OLED devices contain circular polarizers, which are used to reduce reflection from metallic electrodes. A novel OLED display module incorporates a photo-switchable polarizer that transitions between an active polarizing state and an inactive transmissive state, and further contains at least one optical sensor disposed in the OLED display module and adapted to measure light transmitted through the photo-switchable polarizer, and a controller configured to adjust a luminance of the organic electroluminescent layer based on the measured light transmitted through the photo-switchable polarizer.

This patent application claims priority to U.S. Provisional Patent Application No. 62/425,961 filed on Nov. 23, 2016, which is incorporated by reference herein in its entirety.

### FIELD OF THE INVENTION

The present invention relates to an organic light emitting diode (OLED) display module with a photo-switchable polarizer.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

One example of a green emissive molecule is tris(2-phenylpyridine) iridium, denoted Ir(ppy)₃, which has the following structure:

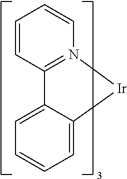

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY

An OLED display module with a photo-switchable polarizer that is capable of maintaining a display luminance that does not appear to change over time is provided.

According to an embodiment, an OLED display module is provided. The OLED display module may include a substrate, a backplane disposed on the substrate, an organic electroluminescent layer formed on the backplane, a photo-switchable polarizer provided on the organic electroluminescent layer, wherein the photo-switchable polarizer transitions between an active polarizing state and an inactive transmissive state, at least one optical sensor disposed in the OLED display module and adapted to measure light transmitted through the photo-switchable polarizer, and a controller configured to adjust a luminance of the organic electroluminescent layer based on the measured light transmitted through the photo-switchable polarizer.

In an embodiment of the invention disclosed herein, the controller in the OLED display module references a predetermined luminance profile to maintain a display luminance that does not appear to change over time.

In an embodiment of the invention disclosed herein, the photo-switchable polarizer transitions between the active polarizing state and the inactive transmissive state depending on a level of intensity of UV light in an ambient light.

In an embodiment of the invention disclosed herein, there is at least two optical sensors disposed in the OLED display module and adapted to measure light transmitted through the photo-switchable polarizer, and wherein a first optical sensor is disposed on the photo-switchable polarizer.

According to another embodiment, a method of manufacturing an OLED display module is provided. The method includes measuring light transmitted through a photo-switchable polarizer, and adjusting a luminance of an organic electroluminescent layer based on the measured light transmitted through the photo-switchable polarizer, wherein the photo-switchable polarizer transitions between an active polarizing state and an inactive transmissive state.

In an embodiment of the invention disclosed herein, the method also includes measuring the light after it passes through the photo-switchable polarizer, and measuring the light before it passes through the photo-switchable polarizer.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an OLED display device including a photo-switchable polarizer.

FIG. 4 shows an OLED display module according to an embodiment of the present invention.

FIG. 5 is a timing diagram showing a native luminance from display pixels (pre-polarization) during a transition from low to bright ambient environment according an embodiment of the present invention.

FIG. 6 is a timing diagram showing a native luminance from display pixels (post-polarization) during a transition from bright to low ambient environment according an embodiment of the present invention.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

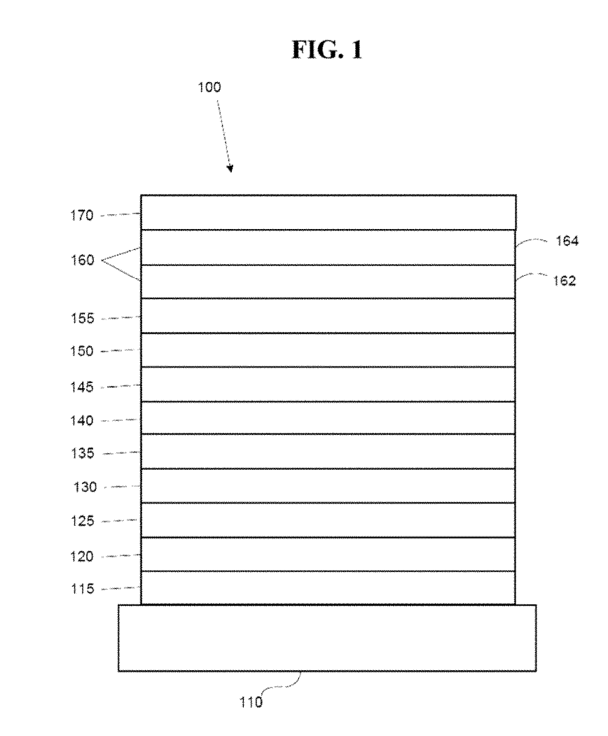

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

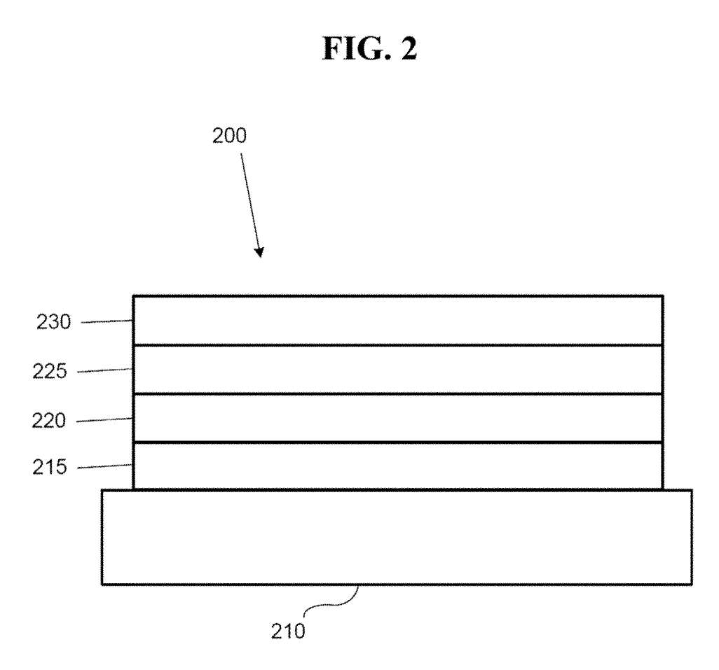

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, cell phones, tablets, phablets, personal digital assistants (PDAs), wearable device, laptop computers, digital cameras, camcorders, viewfinders, micro-displays, 3-D displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.), but could be used outside this temperature range, for example, from −40 degree C. to +80 degree C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

Some OLED devices contain circular polarizers, which are used to reduce reflection from metallic electrodes. Most of theses polarizers transmit less than 45% of incident light, so while the polarizers greatly improve a display contrast, they also reduce display efficiency by more than a factor of two. It has been proposed to use a light or ultraviolet (UV) activated linear polarizer (photo-switchable polarizer) in conjunction with a reverse dispersion layer to form a light activated circular polarizer to overcome this reduced efficiency. The photo-switchable polarizer transitions between an active polarizing state and an inactive transmissive state depending on a level of intensity of UV light. In bright environments, the photo-switchable polarizer is in an active polarizing state transmitting approximately 45% of incident light but blocking the light reflected from a metallic anode or cathode. In dark environments the photo-switchable polarizer is in an inactive transmissive state so close to 100% of incident light would be transmitted. It is understood that the photo-switchable polarizer may be in a various state of transition between a fully active polarizing state and a fully inactive transmissive state depending on the level of intensity of UV light. In other words, depending on the level of intensity of UV light in a certain location, the photo-switchable polarizer of an OLED device may transmit between 45% and 100% of incident light.

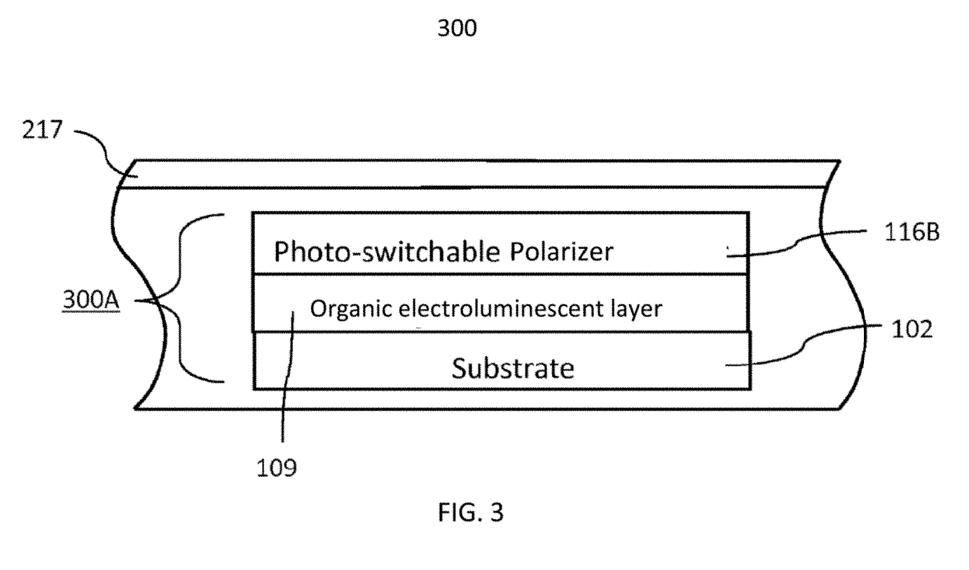

Referring to FIG. 3, an OLED display device 300 is shown. The OLED display device 300 includes a substrate 102, an organic electroluminescent layer 109 provided on the substrate 102, and a photo-switchable circular polarizer layer 116B provided over the organic electroluminescent layer 109. The substrate 102, the organic electroluminescent layer 109, and the photo-switchable polarizer comprises an OLED display module 300A. The photo-switchable polarizer layer 116B transitions between an active polarizing state and an inactive non-polarizing state depending on the level of intensity of UV light in the ambient light of the OLED display module 300A. When the photo-switchable polarizer 116B is in the active polarizing state, the photo-switchable polarizer 116B polarizes the light passing therethrough. On the other hand, when the photo-switchable polarizer 116B is in the inactive transmissive state, the photo-switchable polarizer 116B allows light to pass through without polarizing the light. It is understood that the photo-switchable polarizer 116B is not limited to an active and an inactive state, but the photo-switchable polarizer 116B transitions between an active state and an inactive state. The OLED display device 300 may contain a transparent protective layer 217. A photo-switchable polarizer is described in U.S. Pat. No. 9,444,975, which is herein incorporated by reference in its entireties.

A response time for the photo-switchable polarizer 116B to transition from an active state to inactive state and vise versa depends on light intensity and temperature. In general this may be of the order of seconds or tens of seconds. It is ideal for a display of the OLED display module 300A to maintain the same apparent brightness in any given environment, and not change over time. The relatively slow response time of the photo-switchable polarizer 116B will lead to the display changing brightness as the display is being viewed while it is changing state in response to a change ambient lighting from one level to another, which may be objectionable to a user.

Daylight readable OLED displays operate at close to a white point of 1,000 cd/m² (for example a smart watch, but not limited thereto), so with a 45% efficient polarizer, this implies a native luminance (pre-polarizer) of close to a white point of 2,200 cd/m². Here native display luminance is defined as the display luminance before the polarization. In a dark environment, the smart watch (OLED display) usually operates at around a white point of 400 cd/m², and if the polarizer is in an inactive transmissive state this means that the native display luminance (pre-polarizer) will be close to a white point of 400 cd/m². Between the active state and inactive state, there is a factor of five changes in native display white point luminance. So if the smart watch moves from a bright to dark environment or vice-versa, the native display luminance may change slowly by a factor of five over a period of time. Again, this will be a transition delay, which may be objectionable to a user.

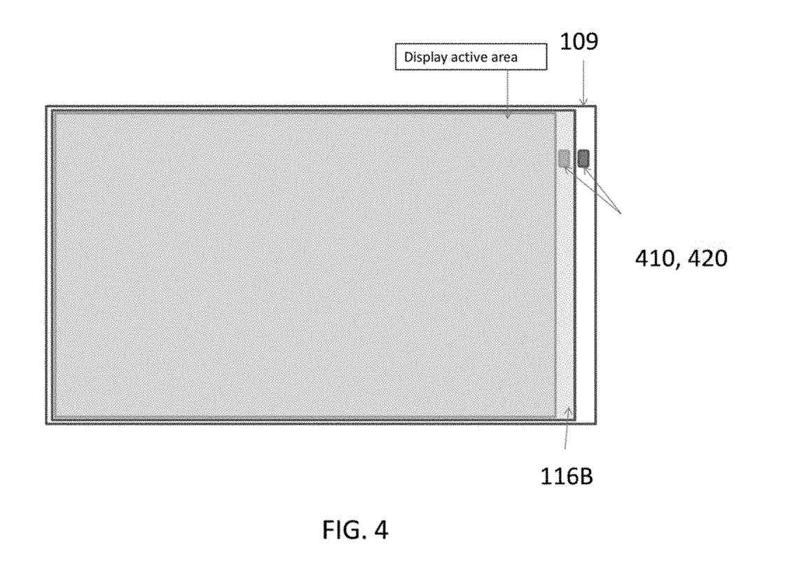

In an embodiment of the present invention is to control a luminance output during a transition period when a photo-switchable polarizer 116B transitions between active and inactive states or vise-versa by measuring light transmitted through the photo-switchable polarizer 116B in real time. Referring to FIG. 4, an embodiment of the present invention provides two identical light sensors 410, 420 incorporated into an OLED display module 300A. One of the light sensor 410 may be covered by the photo-switchable polarizer 116B and the other light sensor 410 not covered by the photo-switchable polarizer 116B. For example, if L₁ is the measured transmittance of light by the light sensor 410, and L₂ is the measured transmittance of light by the light sensor 420, then L₁/L₂ is the transmittance of the photo-switchable polarizer 116B. It should be noted that the number of light sensors 410. 420 and their locations may be varied. For example, one light sensor may be located on the photo-switchable polarizer 116B to measure the transmission of incident of light passing through the photo-switchable polarizer 116B. In another example, there may be two (2) light sensors both covered by the photo-switchable polarizer 116B, and the photo-switchable polarizer 116B may be patterned to expose one of the two light sensors.

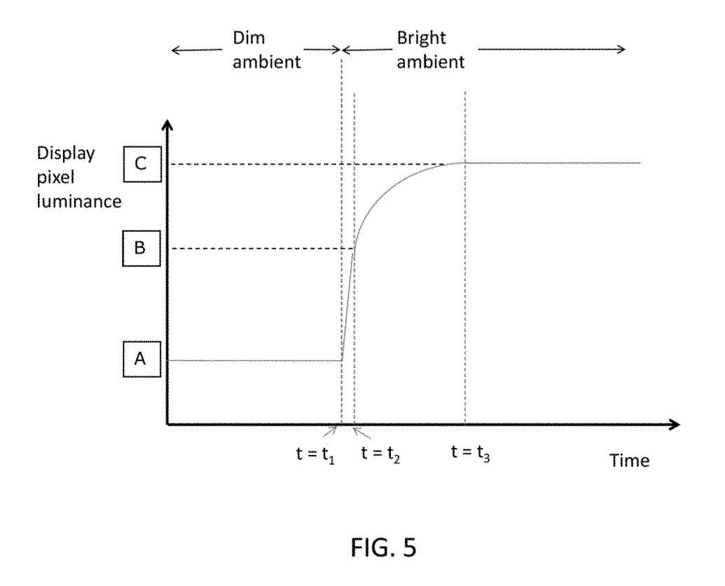

FIG. 5 is a graph showing a display of an OLED device 300 according to an embodiment of the present invention operating in a low light environment with a photo-switchable polarizer 116B fully transmitting close to 100% (inactive transmissive state), and then the OLED device 300 is moved to a bright environment where the photo-switchable polarizer 116B operates at maximum effectiveness (active polarizing state) to remove unwanted reflections from metallic contacts (not shown) in the OLED device 300. Referring to FIG. 5, the organic electroluminescent layer 109 of the OLED device 300 operates at a white point luminance A (e.g. 400 cd/m²) and then transitions to a final white point luminance B (e.g. 1,000 cd/m²). Luminance B may be a user setting or a luminance selected by the OLED display device 300 based on the ambient luminance, independent of the photo-switchable polarizer 116B. To avoid the display luminance changing slowly over a period of time as the photo-switchable polarizer 116B subsequently adjusts, once the OLED display device 300 determines that it has been moved from a low light to a bright light environment (based on an integrated optical sensors 410, 420), the organic electroluminescent layer 109 luminance will switch rapidly from native luminance A to B. This may be accomplished in the order of a frame time, or more gradually if the transition from low to bright light environment occurs more slowly. At luminance A in low light ambient conditions, the photo-switchable polarizer 116B will be approximately 100% transmitting. Once the organic electroluminescent layer 109 has a native white point luminance of B in a bright ambient light the photo-switchable polarizer 116B will start to engage and its transmittance will reduce and will be characterized by L₁/L₂. Over time the organic electroluminescent layer 109 native luminance will be adjusted by a display controller (not shown) to equal BL₂/L₁ to maintain an actual luminance (post-polarizer) of B. In other words, the display controller can adjust the luminance of the organic electroluminescent layer 109 based on the measured light transmitted through the photo-switchable polarizer 116B. Once the photo-switchable polarizer 116B reaches a steady-state and becomes fully active, the native display white point luminance will be C (e.g., 2,200 cd/m²) so that the display maintains white point B after the polarization.

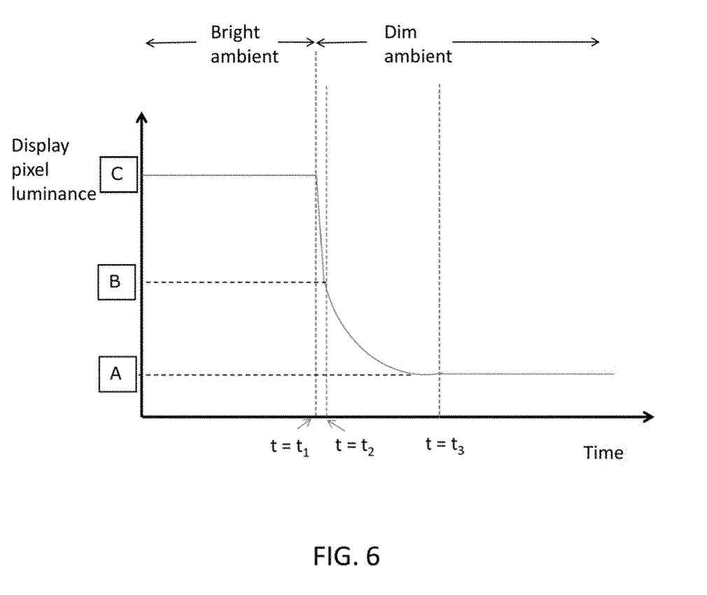

In another embodiment of the present invention, a similar analysis can be made for the OLED device 300 operating in a bright light environment with the photo-switchable polarizer 116B being in its active polarizing state, and then being moved to a low light environment where the photo-switchable polarizer 116B operates at minimum effectiveness, i.e., 100% transmissive state—FIG. 6. Referring to the graph shown in FIG. 6, the organic electroluminescent layer 109 of the OLED display device 300 operates at a native white point luminance C (e.g. 2,200 cd/m²) and then transitions to a final white point luminance A (e.g. 400 cd/m²). Luminance A may be a user setting or a luminance selected by the OLED display device 300 based on the ambient luminance, independent of the photo-switchable polarizer 116B. To avoid the organic electroluminescent layer 109 luminance changing slowly over a period of time as the photo-switchable polarizer 116B subsequently adjusts, once the OLED display device 300 determines that it has been moved from a bright light to a low light environment (based on an integrated optical sensor), the organic electroluminescent layer 109 luminance will switch rapidly from native white point luminance C to the native white point luminance B. This may be accomplished in the order of a frame time, or more gradually if the transition from bright to low environment occurs more slowly. Luminance B corresponds to the luminance at which the display will appear as being at luminance A after the polarization, as just after the transition from bright to low light environment when the photo-switchable polarizer 116B will be fully active. Once the organic electroluminescent layer 109 has a native white point luminance of B in a low ambient light, the photo-switchable polarizer 116B will transition to an inactive transmissive state, the transmittance will increase and will be characterized by L₁/L₂. Over time, the organic electroluminescent layer's 109 native luminance is adjusted by the display controller to equal AL₂/L₁ to maintain an actual luminance (post-polarizer) of A. Once the photo-switchable polarizer 116B has reached steady-state and become fully transmissive, the native the organic electroluminescent layer 109 luminance will be A (e.g., 400 cd/m²) so that the organic electroluminescent layer 109 maintains white point A after the polarizeration.

In many circumstances the ambient light conditions may be dark, very bright, or all conditions in between. In other words, the OLED display device 300 and its display may be in an intermediate state of those shown in FIGS. 2 and 3. Also, an end state of a transition may also be an intermediate state. The OLED display device 300 may select new values for the luminance levels A and B based on these intermediate transition ambient luminances, but the embodiments outlined above may still apply to adjust the native display white point luminance to maintain a specific display luminance as the photo-switchable polarizer 116B adjusts to a new ambient luminance level. The display controller can adjust the luminance of the organic electroluminescent layer 109 to a predetermined luminance profile based on the measured light transmitted through the photo-switchable polarizer 116B. For example, a predetermined luminance profile may be a profile where the display controller increases the luminance of the organic electroluminescent layer 109 as the photo-switchable polarizer 116B transitions from an inactive transmissive state to an active polarizing state and vise versa based on the measured light transmitted through the photo-switchable polarizer 116B. In other words, the predetermined luminance profile is such that even if the OLED display device 300 moves from a low light condition to a bright light condition (and vise versa), the luminance of the display of the OLED display device 300 does not appear to change over time to a user.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. An OLED display module, comprising:
a substrate;
a backplane disposed on the substrate;
an organic electroluminescent layer formed on the backplane;
a photo-switchable polarizer provided on the organic electroluminescent layer, wherein the photo-switchable polarizer transitions between an active polarizing state and an inactive transmissive state;
at least one optical sensor disposed in the OLED display module and adapted to measure light; and
a controller configured to adjust a luminance of the organic electroluminescent layer based on the measured light transmitted through the photo-switchable polarizer.

2. The OLED display module of claim 1, wherein the at least one optical sensor measures the light transmitted through the photo-switchable polarizer, and the controller references a predetermined luminance profile to maintain a display luminance that does not appear to change over time.

3. (canceled)

4. The OLED display module of claim 1, wherein the photo-switchable polarizer transitions between the active polarizing state and the inactive transmissive state depending on a level of intensity of UV light in an ambient light.

5. The OLED display module of claim 1, wherein the controller adjusts a luminance of the organic electroluminescent layer to match the transition states of the photo-switchable polarizer.

6. (canceled)

7. (canceled)

8. The OLED display module of claim 1, wherein the photo-switchable polarizer is a circular polarizer.

9. The OLED display module of claim 1, wherein the OLED display module is integrated in one of a flat panel display, computer monitor, medical monitor, television, billboard, lights for interior or exterior illumination and signaling, heads-up display, laser printer, telephone, cell phone, tablet, phablet, personal digital assistant (PDA), wearable device, laptop computer, digital camera, camcorder, viewfinder, micro-display, 3-D display, vehicle, a large area wall, theater or stadium screen, and a sign.

10. An OLED display module, comprising:
a substrate;
a backplane disposed on the substrate;
an organic electroluminescent layer formed on the backplane;
a photo-switchable polarizer provided on the organic electroluminescent layer, wherein the photo-switchable polarizer transitions between a polarizing active state and an inactive transmissive state;
at least two optical sensors disposed in the OLED display module and adapted measure light transmitted through the photo-switchable polarizer, and wherein a first optical sensor is disposed on the photo-switchable polarizer; and
a controller configured to adjust a luminance of the organic electroluminescent layer based on the measured light transmitted through the photo-switchable polarizer.

11. The OLED display module of claim 10, wherein the controller adjusts the luminance of the organic electroluminescent layer to a predetermined luminance profile based on the measured light transmitted through the photo-switchable polarizer, wherein the controller references the predetermined luminance profile to maintain a display luminance that does not appear to change over time.

12. (canceled)

13. The OLED display module of claim 10, wherein the photo-switchable polarizer is patterned to expose a second optical sensor.

14. The OLED display module of claim 10, wherein the first optical sensor measures the light after it passes through the photo-switchable polarizer, and the second optical sensor measures the light before it passes through the photo-switchable polarizer.

15. The OLED display module of claim 10, wherein the photo-switchable polarizer transitions between the active polarizing state and the inactive transmissive state depending on a level of intensity of UV light in an ambient light.

16. The OLED display module of claim 10, wherein the controller adjusts the luminance of the organic electroluminescent layer to match the transition state of the photo-switchable polarizer.

17. The OLED display module of claim 16, wherein the controller increases the luminance of the organic electroluminescent layer when the photo-switchable polarizer transitions to the active polarizing state, and wherein the controller decreases the luminance of the organic electroluminescent layer when the photo-switchable polarizer transitions to the inactive transmissive state.

18. (canceled)

19. The OLED display module of claim 10, wherein the photo-switchable polarizer is a circular polarizer.

20. The OLED display module of claim 10, wherein the OLED display module is integrated in one of a flat panel display, computer monitor, medical monitor, television, billboard, lights for interior or exterior illumination and signaling, heads-up display, laser printer, telephone, cell phone, tablet, phablet, personal digital assistant (PDA), wearable device, laptop computer, digital camera, camcorder, viewfinder, micro-display, 3-D display, vehicle, a large area wall, theater or stadium screen, and a sign.

21. A method of adjusting a luminance of an OLED display module, comprising:
measuring light transmitted through a photo-switchable polarizer; and
adjusting a luminance of an organic electroluminescent layer based on the measured light transmitted through the photo-switchable polarizer, wherein the photo-switchable polarizer transitions between an active polarizing state and an inactive transmissive state.

22. The method of claim 21, further comprising:
measuring the light after it passes through the photo-switchable polarizer; and,
measuring the light before it passes through the photo-switchable polarizer.

23. The method of claim 21, wherein the adjusting of the luminance of the organic electroluminescent layer includes adjusting the luminance of the organic electroluminescent layer to a predetermined luminance profile, and wherein the predetermined luminance profile is a profile referenced to maintain a display luminance that does not appear to change over time.

24. (canceled)

25. The method of claim 21, wherein the photo-switchable polarizer transitions between the active polarizing state and the inactive transmissive state depending on a level of intensity of UV light in an ambient light.

26. The method of claim 21, further comprising increasing the luminance of the organic electroluminescent layer when the photo-switchable polarizer transitions to the polarizing active state.

27. (canceled)

28. (canceled)
